(19) United States
(12) Patent Application Publication
(10) Pub. No.: US 2026/0155184 A1
(43) Pub. Date: Jun. 4, 2026

(54) ARITHMETIC DEVICE, MEMORY CONTROLLER, AND ARITHMETIC METHOD

(71) Applicant: Kioxia Corporation, Tokyo (JP)

(72) Inventors: Masahiro KUSAKA, Kawasaki Kanagawa (JP); Chikaaki KODAMA, Arakawa Tokyo (JP); Ryo YONEZAWA, Shinagawa Tokyo (JP)

(73) Assignee: Kioxia Corporation, Tokyo (JP)

(21) Appl. No.: 19/322,838

(22) Filed: Sep. 9, 2025

(30) Foreign Application Priority Data
Nov. 29, 2024 (JP) 2024-208243

(51) Int. Cl. G11C 16/10; G11C 16/20; G11C 16/26

(52) U.S. Cl. CPC G11C 16/102; G11C 16/20; G11C 16/26

(57) ABSTRACT

According to one embodiment, a memory controller defines the first state as a state in which a first value is stored, and defines the second state as a state in which a second value is stored. The memory controller maintains a current state of a memory cell in response to a request to write the first value to the memory cell, and shifts the memory cell to the second state in response to a request to write the second value to the memory cell. The arithmetic device is capable of performing logical operations including L×N input AND operations, L×N input NAND operations, L×N input OR operations, or N input NOR operations by performing N write operations of the L-digit value to the memory cell and then reading the value stored in the memory cell.

### CROSS-REFERENCE TO RELATED APPLICATIONS

This application is based upon and claims the benefit of priority from Japanese Patent Application No. 2024-208243, filed Nov. 29, 2024, the entire contents of which are incorporated herein by reference.

### FIELD

Embodiments described herein relate generally to an arithmetic device, a memory controller, and an arithmetic method.

### BACKGROUND

Field programmable gate array (FPGA) is distributed as rewritable hardware that can perform specific calculations at a high speed for a general-purpose central processing unit (CPU).

However, as the number of gates inside FPGA increases and FPGA becomes larger in scale, FPGA becomes more expensive, and FPGA is only used in the development of prototypes and for small-scale production.

For example, when large-scale rewritable hardware is to be developed, a relatively expensive product of FPGA needs to be selected even if a high calculation speed is not required.

### BRIEF DESCRIPTION OF THE DRAWINGS

FIG. 1 is a view showing an example of a configuration of an arithmetic device according to a first embodiment.

FIG. 2 is a first view illustrating a method for the arithmetic device of the first embodiment to construct a two-input AND gate using the memory cells of the flash memory.

FIG. 3 is a second view illustrating a method for the arithmetic device of the first embodiment to construct a two-input AND gate using the memory cells of the flash memory.

FIG. 4 is a view illustrating a method for the arithmetic device of the first embodiment to construct a two-input NAND gate using the memory cells of the flash memory.

FIG. 5 is a first view illustrating a method for the arithmetic device of the first embodiment to construct a two-input OR gate using the memory cells of the flash memory.

FIG. 6 is a second view illustrating a method for the arithmetic device of the first embodiment to construct a two-input OR gate using the memory cells of the flash memory.

FIG. 7 is a view illustrating a method for the arithmetic device of the first embodiment to construct a two-input NOR gate using the memory cells of the flash memory.

FIG. 8 is a view showing an example of constructing an adder using a combination of two-input NAND gates constructed by the arithmetic device of the first embodiment using the memory cells of the flash memory.

FIG. 9 is a view showing an example of connecting several stages of the adders constructed by the arithmetic device of the first embodiment using a combination of the NAND gates.

FIG. 10 is a view showing an example of the instruction codes used to create a program for performing any logical operations using the flash memory in the arithmetic device of the first embodiment.

FIG. 11 is a view showing an example of a program for constructing an adder using the flash memory used in the arithmetic device of the first embodiment.

FIG. 12 is a flowchart showing a procedure for performing logical operations by the arithmetic device of the first embodiment using the memory cells of the flash memory.

FIG. 13 is a view illustrating a method of constructing a two-input AND gate by an arithmetic device of a second embodiment using a multi-level cell flash memory.

FIG. 14 is a view illustrating parallel processing of logical operations in an arithmetic device of a fourth embodiment.

FIG. 15 is a diagram showing an example of an arithmetic device according to an eighth embodiment.

FIG. 16 is a view showing an example of an instruction structure defined by FMOP applied to the arithmetic device of the eighth embodiment.

FIG. 17 is a view showing an example of the instruction code defined by FMOP applied to the arithmetic device of the eighth embodiment.

FIG. 18 is a view showing a configuration example of a parallel-serial conversion circuit in the arithmetic device of the eighth embodiment.

FIG. 19 is a view showing an example of a memory map of the arithmetic device of the eighth embodiment.

FIG. 20 is a view showing an example of execution of a 1-bit addition using a computer architecture to which the arithmetic device of the eighth embodiment is applied.

### DETAILED DESCRIPTION

In general, according to one embodiment, an arithmetic device includes a nonvolatile memory and a controller. The nonvolatile memory includes multiple memory cells each of which is capable of becoming a first state or a second state. The memory controller controls the nonvolatile memory. The memory controller defines the first state as a state in which a first value is stored, defines the second state as a state in which a second value is stored, and initializes the memory cell in the first state, maintains a current state of the memory cell in response to a request to write the first value, and shifts the memory cell to the second state in response to a request to write the second value, and acquires the first value or the second value stored in the memory cell, or the second value or the first value obtained by inverting the first value or the second value stored in the memory cell, between the first value and the second value, as a value stored in the memory cell, in response to a request to read the value stored in the memory cell. The arithmetic device is capable of performing logical operations including L×N input AND operations, L×N input NAND operations, L×N input OR operations, or N input NOR operations by performing N write operations of the L-digit value to the memory cell and then reading the value stored in the memory cell. The N is a natural number greater than or equal to 1.

Embodiments will be described hereinafter with reference to the accompanying drawings.

### First Embodiment

A first embodiment will be described.

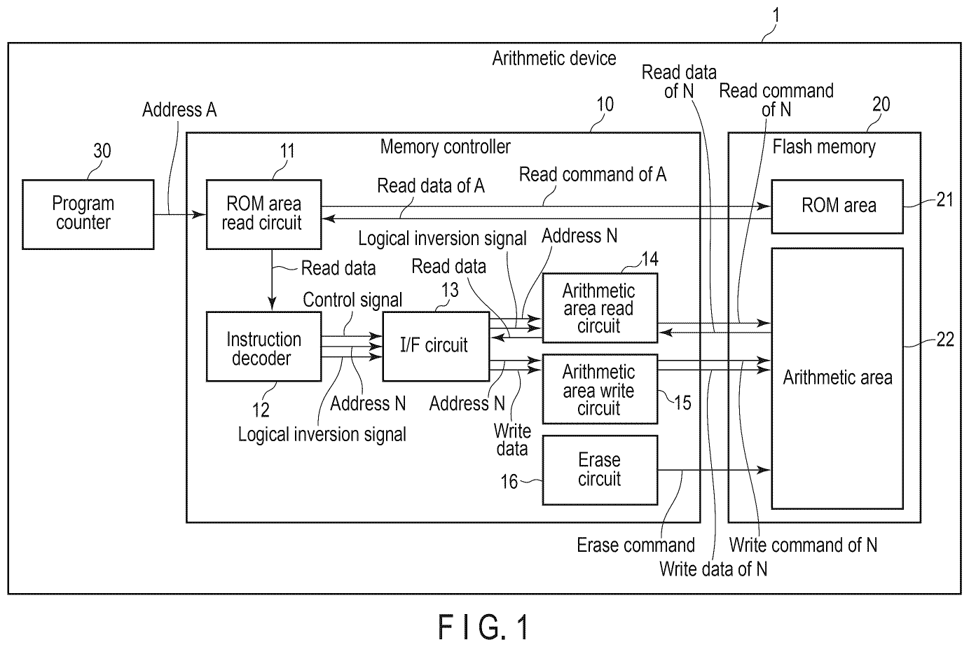

FIG. 1 is a view showing an example of a configuration of an arithmetic device 1 according to the first embodiment.

The arithmetic device 1 includes a memory controller 10, a flash memory 20, and a program counter 3.

The memory controller 10 controls the flash memory 20. More specifically, the memory controller 10 controls a process of writing data to the flash memory 20 and a process of reading data from the flash memory 20.

The flash memory 20 is a nonvolatile memory that includes multiple memory cells. The flash memory 20 may be of the NAND type or the NOR type. Furthermore, an example in which the arithmetic device 1 uses the flash memory 20 will be described here. However, the arithmetic device 1 may also use a nonvolatile memory other than the flash memory 20 as described later.

The program counter 30 is a device that supplies addresses to the memory controller 10 such that the program for logical operations to be described later, which is stored in the flash memory 20, is read one step after one step.

The arithmetic device 1 of the first embodiment realizes constructing any logic circuit, like FPGA, but at a cost much lower than FPGA, by having the memory controller 10 control the process of writing to the flash memory 20 and the process of reading from the flash memory 20. This point will be described below in detail. Incidentally, in the arithmetic device 1 of the first embodiment, constructing any logic circuit means performing logical operations that are equivalent to any logic circuits. In other words, constructing any logic circuit is to logically construct an arbitrary logic circuit.

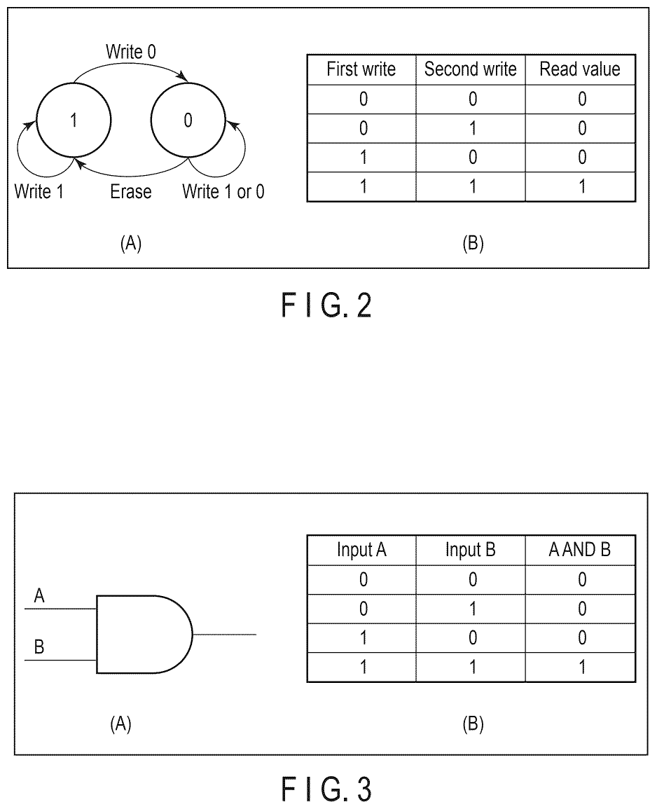

An example of a method of constructing a logic circuit by writing to and reading from the flash memory 20 will be described with reference to FIG. 2 to FIG. 4 here.

For example, an initial state in which no electrons are stored in the floating gate is defined as “1”. When writing “0”, which indicates applying a voltage to the control gate to allow electrons to flow into the floating gate, is performed even once, in the memory cell of the flash memory 20, the value is not changed even if overwritten with “1” after that. In other words, the value is ignored. FIG. 2(A) shows a state transition of a read value of the memory cells of the flash memory 20 in a case where “0” or “1” is written to the memory cells of the flash memory 20. In addition, an erase operation to return the memory cells to their initial state is realized by applying a voltage to the silicon substrate and causing the electrons stored in the floating gate to flow to the silicon substrate side.

FIG. 2(B) shows read values from the memory cells of the flash memory 20 in a case where writing to the memory cells of the flash memory 20 is performed two times.

As shown in FIG. 2(B), when “0” is written to the memory cells of the flash memory 20 for the first time and “0” is written for the second time, the read value from the memory cells of the flash memory 20 is “0”. In addition, if “0” is written for the first time and “1” is written for the second time, the read value is “0”. Similarly, the read value is “0” if “1” is written for the first time and “0” is written for the second time, and the read value is “1” if “1” is written for the first time and “1” is written for the second time.

For example, the arithmetic device 1 of the first embodiment assumes the first write as input A, the second write as input B, and the read value after the second write as output. Based on the assumption, the arithmetic device 1 of the first embodiment constructs a two-input AND gate as shown in FIG. 3(A) by writing to and reading from the memory cells of the flash memory 20. FIG. 3(B) is a truth table of a two-input AND gate. The values of “A AND B” shown in FIG. 3(B) are the same as the “read values” shown in FIG. 2(B).

Thus, the arithmetic device 1 of the first embodiment can perform AND operations between write data by utilizing the characteristics of the memory cells of the flash memory 20. The arithmetic device 1 of the first embodiment can construct not only the above-described two-input AND gate, but also an N-input (N is a natural number greater than or equal to 2) AND gate.

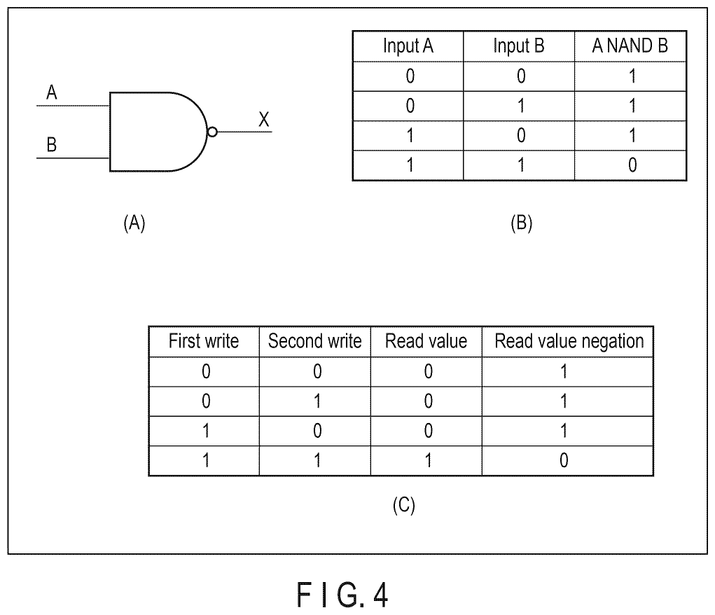

In addition, the arithmetic device 1 of the first embodiment can construct a 2-input NAND gate as shown in FIG. 4(A) by inverting the read values from the memory cells of the flash memory 20 in some manner. FIG. 4(B) is a truth table of the 2-input NAND gate. In addition, in the table of FIG. 4(C), a column of read value negations, which are the values obtained by inverting the read values from the memory cells of flash memory 20, is added to the table in FIG. 2(B). The values of “A NAND B” shown in FIG. 4(B) are the same as the “read value negations” shown in FIG. 4(C), which are obtained by inverting the “read values”.

For example, the following three methods are considered as methods of inverting the read values from the memory cells of flash memory 20.
(1) Inverting with a program referred to as firmware or the like that operates in the memory controller 10 (the program that constructs an arithmetic area read circuit 14 to be described below).
(2) Providing a NOT gate on a line on which the read values are transferred from the flash memory 20 in the bus between the memory controller 10 and the flash memory 20 to the memory controller 10.
(3) Determining “1” which the flash memory 20 normally determines, as “0” in a case where the threshold voltage of the memory cells is low, when reading. The threshold voltage is the voltage at which a current starts to flow between the source and the drain of the memory cell. In the memory cell, a current easily flows in an initial state (erased state or unwritten state) in which no electrons are stored in the floating gate, and a current hardly flows in a written state in which electrons are stored in the floating gate. In other words, the read value is inverted according to the determination made when reading from the memory cell by the flash memory 20.

Thus, the arithmetic device 1 of the first embodiment can perform NAND operations on the write data by utilizing the characteristics of the memory cells of the flash memory 20. In other words, the arithmetic device 1 of the first embodiment can logically construct a NAND gate using the flash memory 20.

It is known that the NAND gate has “functional completeness (also referred to as functional compatibility)” as a standalone device. Therefore, in the arithmetic device 1 of the first embodiment, any logic circuit can be constructed depending on the combination of NAND gates.

Thus, the arithmetic device 1 of the first embodiment can construct any logic circuit by writing to and reading from the flash memory 20.

Next, another example of the method of constructing the logic circuit by writing to and reading from flash memory 20 will be described with reference to FIG. 5 to FIG. 7.

In another method, the arithmetic device 1 of the first embodiment defines the initial state in which no electrons are stored in the floating gate, in the memory cells of the flash memory 20, as “0”, which is the opposite of the normal definition. In this case, when writing “1” to apply a voltage to the control gate and to allow electrons to flow into the floating gate is performed, the value is not changed even if the value is overwritten with “0”.

FIG. 5(A) shows the state transitions of the memory cells in the flash memory 20 in a case where “0” or “1” is written to the memory cells of the flash memory 20 when the definitions of “0” and “1” are reversed.

In addition, FIG. 5(B) shows the read values from the memory cells of the flash memory 20 in a case where writing to the memory cells of the flash memory 20 is performed two times.

As shown in FIG. 5(B), when “0” is written to the memory cells of the flash memory 20 for the first time and “0” is written for the second time, the read value from the memory cells of the flash memory 20 is “0”. In addition, if “0” is written for the first time and “1” is written for the second time, the read value is “1”. Similarly, the read value is “1” if “1” is written for the first time and “0” is written for the second time, and the read value is “1” if “1” is written for the first time and “1” is written for the second time.

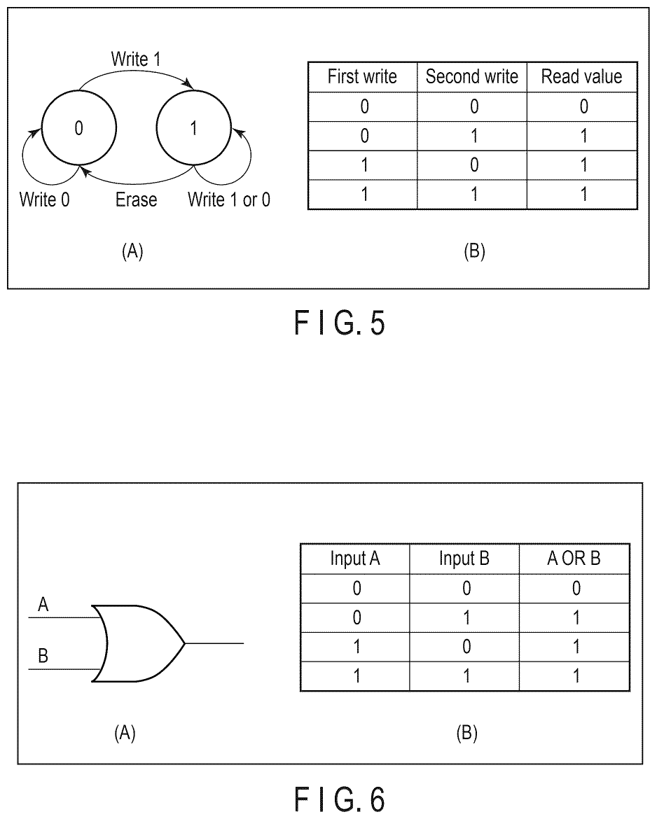

As described above, the arithmetic device 1 of the first embodiment constructs a two-input OR gate as shown in FIG. 6(A) by writing to and reading from the memory cells of the flash memory 20, assuming that the first write is input A, the second write is input B, and the read value after the second write is output. FIG. 6(B) is a truth table of the two-input OR gate. The values of “A OR B” shown in FIG. 6(B) are the same as the “read values” shown in FIG. 5(B).

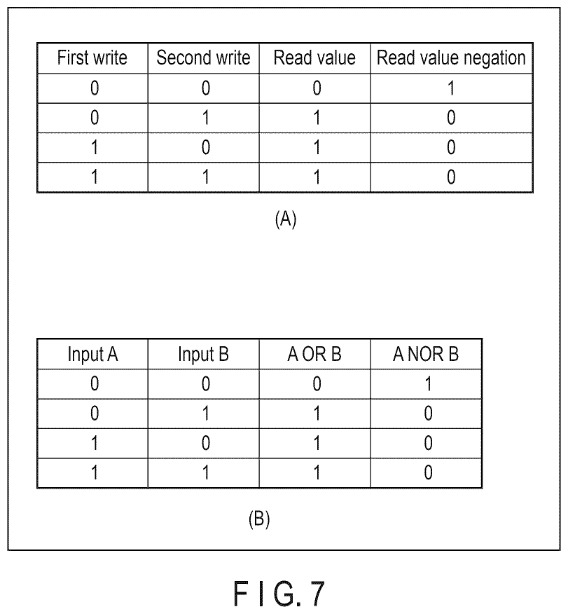

In addition, FIG. 7(A) shows the read values and the read value negations from the memory cells of the flash memory 20 in a case where the definitions of “0” and “1” are reversed and writing to the memory cell of the flash memory 20 is performed two times.

As shown in FIG. 7(A), when “0” is written to the memory cells of the flash memory 20 for the first time and “0” is written for the second time, the read value from the memory cells of the flash memory 20 is “0” and the read value negation is “1”. In addition, if “0” is written for the first time and “1” is written for the second time, the read value is “1” and the read value negation is “0”. Similarly, the read value is “1” and the read value negation is “0” if “1” is written for the first time and “0” is written for the second time, and the read value is “1” and the read value negation is “0” if “1” is written for the first time and “1” is written for the second time.

In addition, FIG. 7(B) is a truth table of a 2-input OR gate and a 2-input NOR gate. The values of “A OR B” shown in FIG. 7(B) are the same as the “read values” shown in FIG. 7(A), and the values of “A NOR B” shown in FIG. 7(B) are the same as the “read value negations” shown in FIG. 7(A).

Thus, the arithmetic device 1 of the first embodiment can perform OR operations between write data by utilizing the characteristics of the memory cells of the flash memory 20, and perform NOR operations between the write data by inverting the read data from the memory cells of the flash memory 20.

In other words, the arithmetic device 1 of the first embodiment can logically construct a NOR gate using the flash memory 20.

It is known that the NOR gate has “functional completeness (also referred to as functional compatibility)” as a standalone device. Therefore, in the arithmetic device 1 of the first embodiment, any logic circuit can be constructed depending on the combination of NOR gates.

Thus, the arithmetic device 1 of the first embodiment can construct any logic circuit by writing to and reading from the flash memory 20.

The example of using the characteristics of the flash memory 20 that even if writing by applying a voltage to the control gate and causing electrons to flow into the floating gate is performed even once, a voltage is applied to the silicon substrate and the state is not changed until erasure to cause the electrons stored in the floating gate to flow out to the silicon substrate side, has been described. Instead of this, if the memory controller 10 controls the nonvolatile memory so as to artificially reproduce the characteristics of the flash memory 20, the arithmetic device 1 of the first embodiment can also apply a nonvolatile memory other than the flash memory 20.

More specifically, for example, if the initial state of each memory area of the nonvolatile memory to be applied is defined as “1”, the memory controller 10 only needs to control the process of writing to the target memory area only when the write data is “0”. In other words, if the write data is “1”, the process of writing to the target memory area is omitted. It is thereby possible to construct an AND gate with multiple inputs (N input AND gate where N is a natural number greater than or equal to 2) in which the read value is “1” if “0” is never written or the read value is “1” if “0” is written even once.

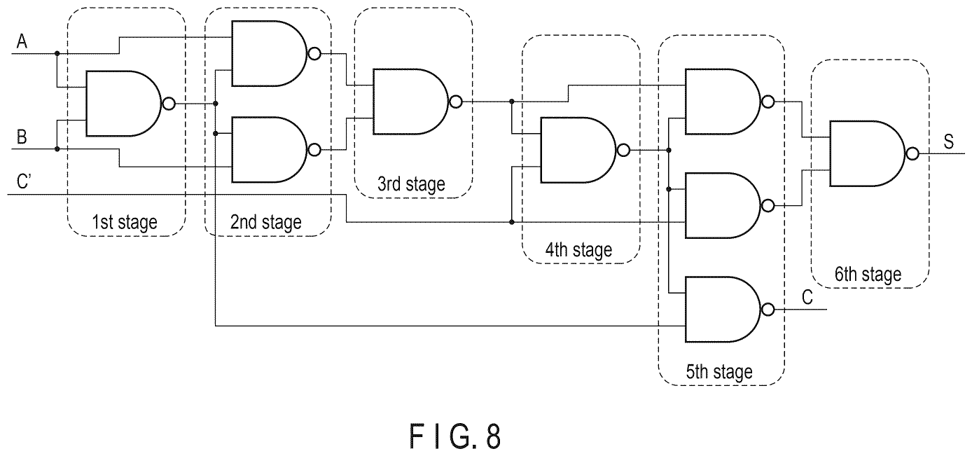

FIG. 8 shows an example of using the memory cells of the flash memory 20 as NAND gates to construct an adder in the arithmetic device 1 of the first embodiment.

In FIG. 8, input A and input B are two values of the digit to be added. Input C′ is a carry value from a lower digit. Output S is a value of the digit obtained as an addition result, and output C is a carry value to an upper digit.

Thus, the arithmetic device 1 of the first embodiment can construct a single-digit adder by combining six stages of NAND gates configured using the memory cells of the flash memory 20.

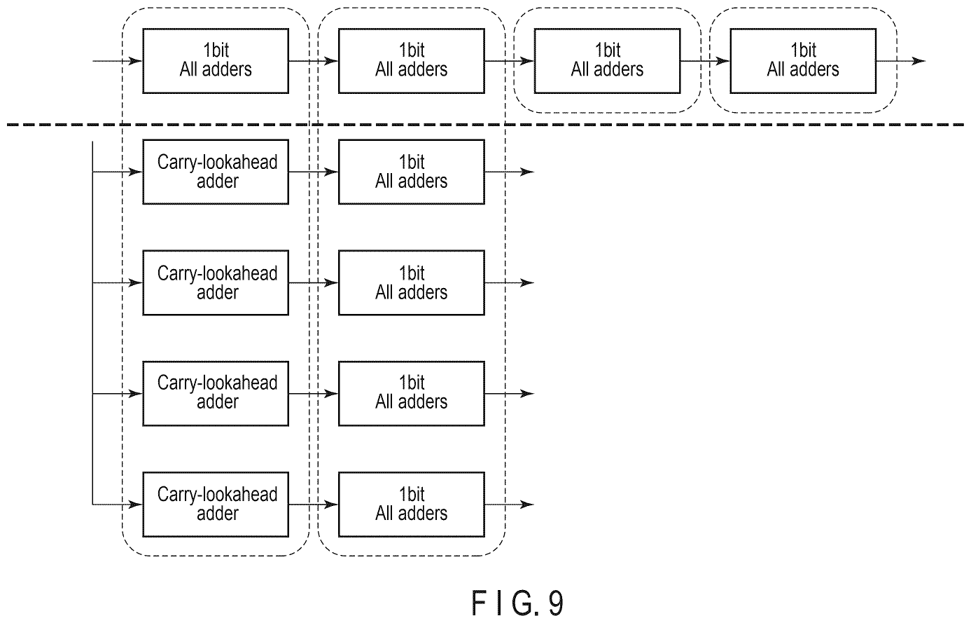

In addition, FIG. 9 also shows an example of connecting several stages of adders configured as described above.

In FIG. 9, an upper part of a broken line is an example of connecting multiple adders in series. In contrast, an upper part of the broken line is an example of connecting multiple adders in parallel using carry-lookahead adders.

The arithmetic device 1 of the first embodiment requires, for example, multiple write operations to the flash memory 20 and a single read operation from the flash memory 20 for a single NAND operation, but critical paths can be reduced by applying conventional technology such as a carry-lookahead adder.

Description of the example of the configuration of the arithmetic device 1 of the first embodiment will be restarted with reference to FIG. 1.

The memory controller 10 includes a ROM area read circuit 11, an instruction decoder 12, an interface (I/F) circuit 13, an arithmetic area read circuit 14, an arithmetic area write circuit 15, and an erase circuit 16.

The ROM area read circuit 11 is a module that reads the program for logical calculation from the ROM area 21 secured in the flash memory 20. The memory controller 10, for example, secures the ROM area 21 where the program is stored and the calculation area 22 used for logical calculation within the flash memory 20.

The ROM area read circuit 11 reads out a program from the ROM area 21 of the flash memory 20 for one step, based on an address sent from the program counter 30. The ROM area read circuit 11 transfers the read program for one step to the instruction decoder 12.

The instruction decoder 12 is a module that interprets the program for one step received from the ROM area read circuit 11. As a result of the interpretation, for example, the instruction decoder 12 outputs a command to read data from the arithmetic area 22 of the flash memory 20 or a command to write data to the arithmetic area 22 of the flash memory 20 to the interface circuit 13. When outputting these commands, the instruction decoder 12 also outputs an address of a read target or a write target of the arithmetic area 22 to the interface circuit 13.

In addition, when outputting a data read command to the interface circuit 13, the instruction decoder 12 outputs to the interface circuit 13 a control signal to cause the command to be output to the arithmetic area read circuit 14. In contrast, when outputting a data write command to the interface circuit 13, the instruction decoder 12 outputs to the interface circuit 13 a control signal to cause the command to be output to the arithmetic area write circuit 15. Furthermore, the instruction decoder 12 outputs to the interface circuit 13 a logical inversion signal to invert the read value to the read value negation as necessary.

The interface circuit 13 is a module that operates as a demultiplexer. The interface circuit 13 selectively outputs the command received from the instruction decoder 12 to the arithmetic area read circuit 14 or the arithmetic area write circuit 15, based on the control signal input from the instruction decoder 12.

The arithmetic area read circuit 14 issues a command to read the data received from the interface circuit 13 for the flash memory 20. At this time, the arithmetic area read circuit 14 adds the address received from the interface circuit 13 to the data read command. This address indicates the arithmetic area 22 of the flash memory 20. The arithmetic area read circuit 14 transfers the read value from the arithmetic area 22 of the flash memory 20 to the interface circuit 13. This read value is stored in, for example, a register in the memory controller 10 via the interface circuit 13.

The arithmetic area write circuit 15 issues a command to write the data received from the interface circuit 13 for the flash memory 20. At this time, the arithmetic area write circuit 15 adds the address received from the interface circuit 13 to the data write command. This address indicates the arithmetic area 22 of the flash memory 20.

The erase circuit 16 is a module that controls the erasure for returning memory cells that have been used in the logical operations in the arithmetic area 22 of the flash memory 20, to the initial state. More specifically, the erase circuit 16 issues an erase command to the flash memory 20 for a portion of the arithmetic area 22. As the memory cells in the arithmetic area 22 are consumed in the logical operations, the memory cells in the initial state decrease. The memory controller 10 executes erasure for returning the used memory cells to the initial state, using the erase circuit 16 as necessary.

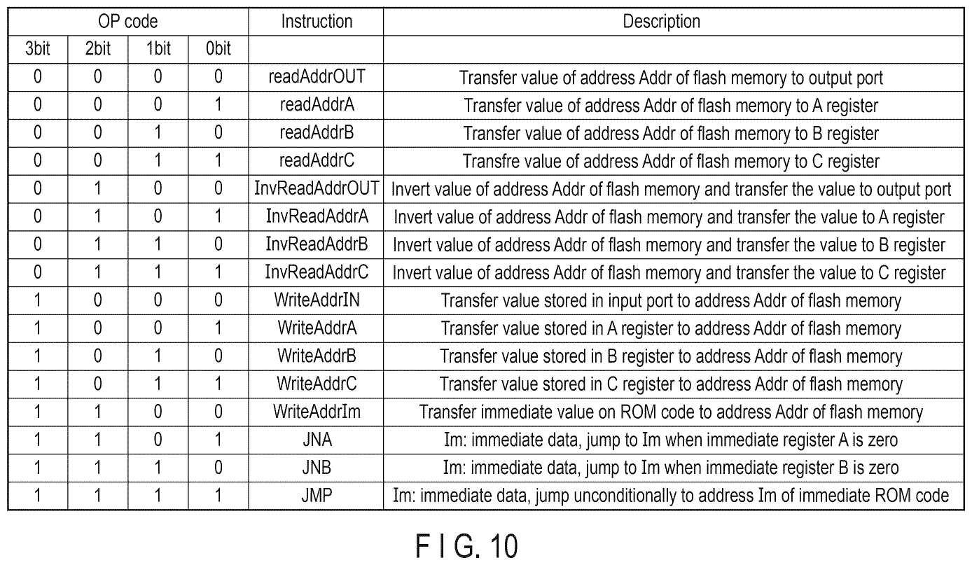

FIG. 10 is a view showing an example of instruction codes used to create a program for performing any logical operations using the flash memory in the arithmetic device 1 of the first embodiment. FIG. 10 shows sixteen instruction codes identified by 4 bits. Programs for performing any logical operations are created using these instruction codes and stored in the ROM area 21 of the flash memory 20.

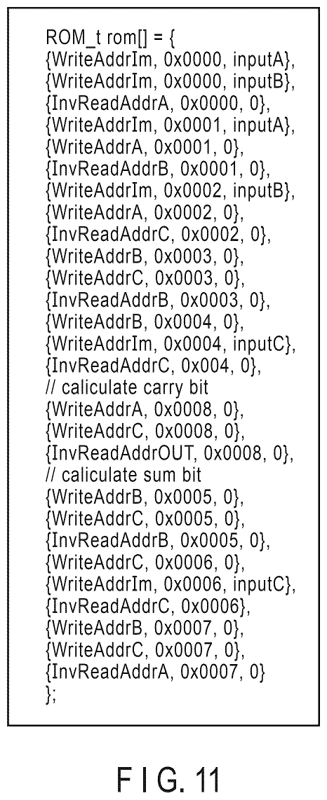

In addition, FIG. 11 shows an example of a program for performing logical operations equivalent to the adder shown in FIG. 8, which is created using the instruction codes shown in FIG. 10.

The ROM area read circuit 11 reads, for example, one step of the program shown in FIG. 11 from the ROM area 21, based on the address received from the program counter 30. The instruction decoder 12 converts one step of the program received from the ROM area read circuit 11 into any one of the commands shown in FIG. 10. The instruction decoder 12 transfers the converted command to the arithmetic area read circuit 14 or the arithmetic area write circuit 15 via the interface circuit 13.

Accordingly, the arithmetic device 1 of the first embodiment performs logical operations by reading and writing to the memory cells of the flash memory 20.

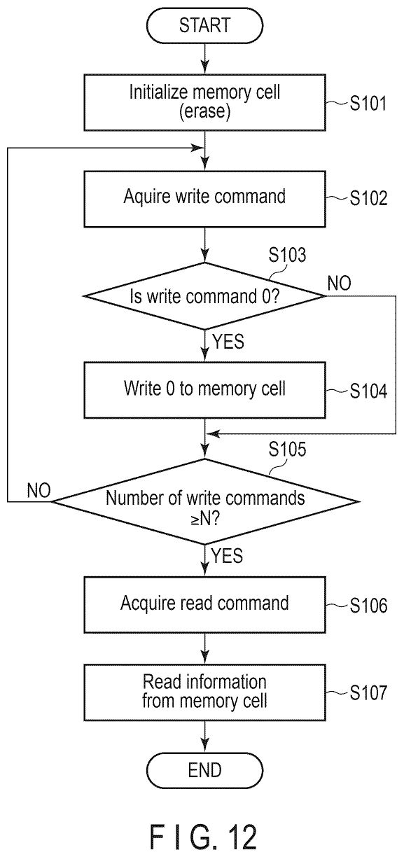

FIG. 12 is a flowchart showing a procedure for performing logical operations by the arithmetic device 1 of the first embodiment using the memory cells of the flash memory 20. An example of performing N-input AND operations or N-input NAND operations will be described here. In other words, it is assumed that the initial state of the memory cells is defined as “1” and that the write state in which electrons are stored in the floating gate is defined as “0”.

The memory controller 10 first initializes the memory cells in an operation area 22 of the flash memory 20 using the erase circuit 16 (S101). This initialization is desirably performed in advance.

The memory controller 10 acquires the write command described in the program stored in the ROM area 21 using the ROM area read circuit 11 (S102). The memory controller 10 then determines whether the write data is “0” or “1” (S103).

If the write data is “0” (S103: YES), the memory controller 10 writes “0” to the memory cells using the arithmetic area write circuit 15 (S104). If the write data is “1” (S103: NO), the memory controller 10 skips the write process to the memory cells. Since the flash memory 20 is assumed to be the nonvolatile memory, the memory controller 10 may write “1” to the memory cell using the arithmetic area write circuit 15.

The memory controller 10 determines whether or not the number of write commands acquired has reached N (S105). If the number is less than N (S105: NO), the memory controller 10 returns to S102 and acquires a next write command.

If the number of write commands has reached N (S105: YES), the memory controller 10 acquires a read command this time using the ROM area read circuit 11 (S106). The memory controller 10 then reads the information from the memory cells using the arithmetic area read circuit 14 (S107).

The information corresponds to an N-input AND operation result. In addition, when reading the information from the memory cells, the memory controller 10 may perform a process of inverting the information. The inverted information corresponds to an N-input NAND operation result.

As described above, the arithmetic device 1 of the first embodiment can logically construct at least an AND gate or a NAND gate by reading and writing to the memory cells of the flash memory 20.

In addition, the arithmetic device 1 of the first embodiment can logically construct at least an OR gate or a NOR gate by reversing the definitions of “0” and “1” corresponding to the state of the memory cells of the flash memory 20.

As described above, it is known that the NAND gate and the NOR gate have “functional completeness (also referred to as functional compatibility” as standalone devices. Therefore, in the arithmetic device 1 of the first embodiment, any logic circuit can be constructed depending on the combination of NAND gates or NOR gates.

Accordingly, the arithmetic device 1 of the first embodiment realizes large-scale, rewritable hardware at a low cost as compared to, for example, FPGA.

In addition, although not shown in FIG. 1, the arithmetic device 1 of the first embodiment can also construct basic elements of a computer by further securing a main memory area used as a work area for programs which perform logical operations and an auxiliary memory area in which information used in the programs is stored, in the flash memory 20.

In the computer constructed by the arithmetic device 1 of the first embodiment, all information in the flash memory 20 including the main memory area is retained even when the power is cut off. Therefore, calculations can be resumed immediately after the power is turned back on after the power has been cut off. In addition, it is possible to easily debug the program when a problem occurs, for example, by tracking the logical operation process.

### Second Embodiment

Next, a second embodiment will be described.

The arithmetic device 1 of the first embodiment is premised on the flash memory 20 of single level cell (SLC). In contrast, a multi-level cell flash memory 20 such as a multi-level cell (MLC), a triple-level cell (TLC), or a quad-level cell (QLC) is applied as an arithmetic device 1 of a second embodiment.

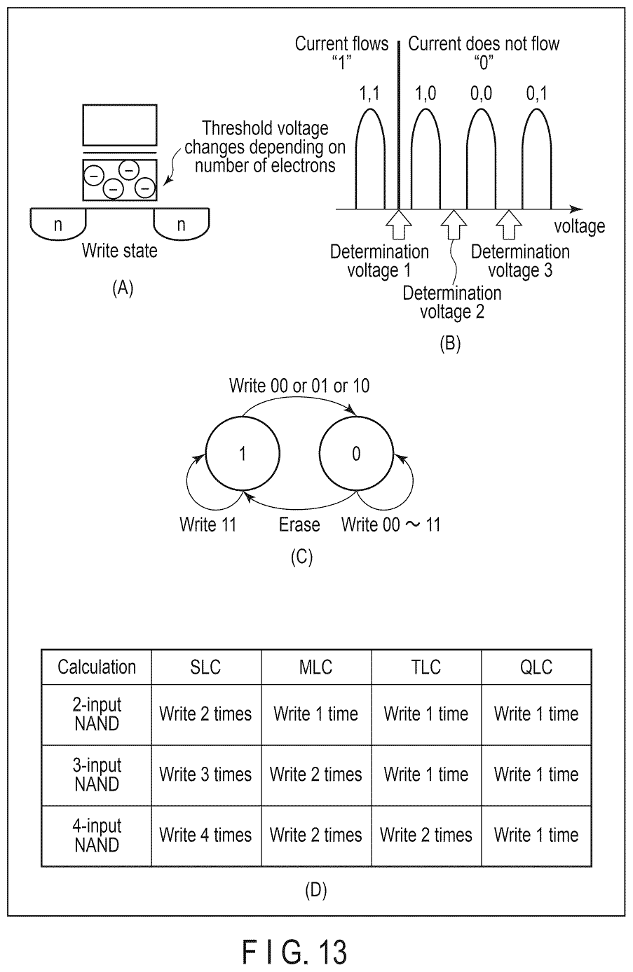

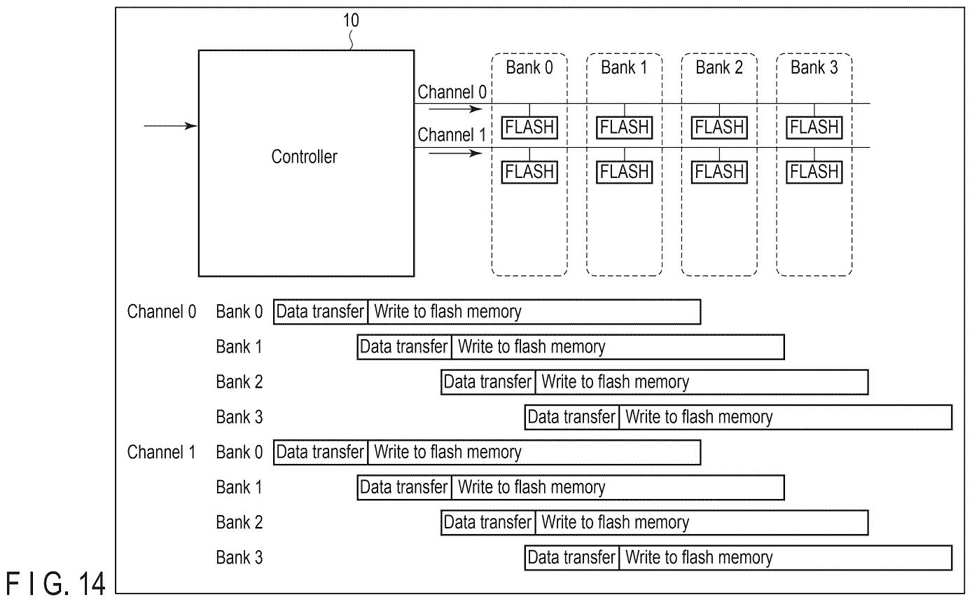

For example, in the MLC, the memory cells of flash memory 20 store two values “0, 0”, “0, 1”, “1, 0”, or “1, 1”. FIG. 13(A) schematically shows a write state in which electrons are stored in the floating gate of the memory cell of the flash memory 20. The flash memory 20 of the MLC can record two values by setting four distributions as shown in FIG. 13(B), paying attention to a fact that the threshold voltage changes depending on the number of electrons stored in the floating gate.

In a case where the two values are associated with each distribution as shown in FIG. 13(B), “1, 1” is recorded if a current flows at determination voltage 1. In other words, the read value is “1, 1”. Incidentally, the state of the read value “1, 1” in which a current flows at the smallest determination voltage 1, is the initial state (erase state) of the memory cell.

If no current flows at determination voltage 1 but a current flows at determination voltage 2, the read value is “1, 0”. Alternatively, if no current flows at determination voltages 1 and 2 but a current flows at determination voltage 3, the read value is “0, 0”. If no current flows at determination voltage 3 either, the read value is “0, 1”.

In contrast, the arithmetic device 1 of the second embodiment determines that the read value is “1” if a current flows at determination voltage 1 while the read value is “0” if no current flows at determination voltage 1, as shown in FIG. 13(B). More specifically, the read value “1, 1” is determined to be “1”, and the read values “1, 0”, “0, 0”, and “0, 1” are determined to be “0”. In other words, four values are combined into two values.

FIG. 13(C) shows state transitions of the read values of the memory cells of the flash memory 20 in the MLC flash memory 20 in the arithmetic device 1 of the second embodiment in a case where “0, 0”, “0, 1”, “1, 0”, or “1, 1” are written to the memory cells of the flash memory 20.

As can be recognized in FIG. 13(C), when writing “0, 1”, “1, 0”, or “1, 1” including “1” is performed, the read value of the memory cell becomes “0” in the arithmetic device 1 of the second embodiment.

In the arithmetic device 1 of the first embodiment, writing to the memory cell needs to be performed twice in order to perform a two-input AND operation. In contrast, in the arithmetic device 1 of the second embodiment, the two-input AND operation can be performed with a single write to the memory cell. In addition, the two-input NAND operation for inverting the read value of the memory cell is performed in the same manner. Furthermore, the two-input OR operation and the two-input NOR operation can also be performed with a single write to the memory cell by changing association of the two-value with each distribution.

FIG. 13(D) is a table showing the number of times of writes to the memory cell for each combination of the memory cell type and the N-input NAND operation.

For example, a 3-input NAND operation can be performed with a single write to the memory cell, in the memory cells of TLC, and a 4-input NAND operation can be performed with a single write to the memory cell, in the memory cells of QLC.

Incidentally, for example, in the memory cells of TLC and QLC, a two-input NAND operation can also be performed with a single write to the memory cell, but one input is missing in TLC and two inputs are missing in QLC. For this reason, inputs which are not used for operation are supplemented with one input in the arithmetic device 1 of the second embodiment.

As described above, the arithmetic device 1 of the second embodiment can logically construct, for example, a multi-input NAND gate with the smaller number of times of writes to the memory cells of the flash memory 20.

As a result, the arithmetic device 1 of the second embodiment can increase its operation speed as compared to the arithmetic device 1 of the first embodiment.

### Third Embodiment

Next, a third embodiment will be described.

For example, the arithmetic device 1 of the first embodiment logically constructs a NAND gate or NOR gate that is known as having “functional completeness (also referred to as functional compatibility)” as a standalone device by performing N writes and a single read to the memory cells and inverting the read value from the memory cells. The arithmetic device 1 of the first embodiment, which can logically construct a NAND gate or a NOR gate, can construct any logic circuit depending on the combination of NAND gates or NOR gates.

For example, the following three methods can be considered as a method of inverting the read value from the memory cells, as described above.
(1) Inverting by a program referred to as firmware that operates in the memory controller 10 (i.e., a program that constitutes the arithmetic area read circuit 14).
(2) Providing a NOT gate on a line on which the read values are transferred from the flash memory 20 in the bus between the memory controller 10 and the flash memory 20 to the memory controller 10.
(3) Determining “1” which the flash memory 20 normally determines, as “0” in a case where the threshold voltage of the memory cells is low, when reading.

An arithmetic device 1 of the third embodiment comprises a function of turning on/off the function of inverting the read value, by, for example, issuing a command to the memory controller 10 or inputting a control signal to the flash memory 20 via the memory controller 10. In the method of providing a NOT gate in (2), the NOT gate is configured to be disabled under the control of the memory controller 10.

In other words, for example, the arithmetic device 1 of the third embodiment can operate as a device that can construct any logic circuit such as FPGA and can operate as a storage device that stores data by turning off the function of inverting the read values from the memory cells.

In addition, the arithmetic device 1 of the third embodiment can switch the function of turning on/off the function of inverting the read values from the memory cells not for the entire flash memory 20, but for each predetermined area unit. In this case, securing the auxiliary storage area for configuring the basic elements of a computer, as described in the first embodiment, may be performed by turning off the function of inverting the read values from the memory cells.

As described above, the arithmetic device 1 of the third embodiment can operate as either (1) a device that can construct any logic circuit such as FPGA or (2) a storage device that stores data, by comprising the function of turning on/off the function of inverting the read values from the memory cells.

### Fourth Embodiment

Next, a fourth embodiment will be described.

For example, the arithmetic device 1 of the first embodiment performs logical operations by reading and writing to memory cells. For this reason, when constructing a large-scale logic circuit, the throughput from the time when the input is supplied to the time when the output is obtained decreases.

In contrast, the flash memory 20 usually includes multiple memory dies each including multiple memory cells. A memory die is also referred to as a memory chip. Each of the memory dies can operate independently. In other words, the memory die functions as a parallel operation unit of the flash memory 20.

Therefore, the arithmetic device 1 of the fourth embodiment improves throughput by performing parallel processing of logical operations using multiple memory dies.

FIG. 14 is a view illustrating the parallel processing of logical operations in the arithmetic device 1 of the fourth embodiment.

In FIG. 14, “FLASH” is a memory die of the flash memory 20. The memory dies are connected to each channel in equal numbers. In FIG. 14, four memory dies are connected to each of the two channels. In addition, every two memory dies connected in parallel to channels 1 and 2 are organized as banks. The bank functions as a unit for causing multiple memory dies to execute the parallel operation by bank interleaving. In the example shown in FIG. 14, eight memory dies can be made to perform the parallel operation by bank interleaving using four banks over two channels.

The arithmetic device 1 of the fourth embodiment performs parallel processing of logical operations using eight memory dies as shown in, for example, FIG. 14. More specifically, data transfer is performed in each channel in time division to each memory die, and writing the data is performed independently in each memory die.

As a result, the arithmetic device 1 of the fourth embodiment can improve the throughput of the logic circuit configured using the flash memory 20.

### Fifth Embodiment

Next, a fifth embodiment will be described.

As described in the first embodiment, for example, the memory cells in the initial state are depleted as the memory cells of the flash memory 20 are consumed for logical operations. Therefore, the memory controller 10 performs erasure to return the used memory cells to their initial state using the erase circuit 16 as necessary.

If the memory cells in the initial state are depleted during the logical operations, completion of the erasure which is performed for the used memory cells needs to be awaited, which greatly reduces the throughput of the logical operations.

Accordingly, for example, the arithmetic device 1 of the fifth embodiment prevents occurrence of the situation in which the memory cells in the initial state are depleted the logical operations, by controlling the use of the memory dies that function as parallel operation units of the flash memory 20 as described in the fourth embodiment.

More specifically, for example, the memory controller 10 rotates the erasure of memory cells using the erase circuit 16 for each memory die, and performs the logical operations using the memory dies in banks other than the bank that includes the memory die being erased.

As a result, the arithmetic device 1 of the fifth embodiment prevents the throughput of the logic circuit configured using the flash memory 20 from decreasing due to the depletion of the memory cells.

### Sixth Embodiment

Next, a sixth embodiment will be described.

A flash memory 20 is deteriorated each time writing and erasing are performed. For this reason, the flash memory 20 is periodically subjected to a fault diagnosis. A memory die includes multiple blocks, and the fault diagnosis is usually performed on a block-by-block basis. A block which is determined to be faulty in the fault diagnosis is managed so as not to be used in the future as a faulty block.

The logical operations cannot be performed on a memory die including a block which is being subjected to a fault diagnosis. Therefore, the arithmetic device 1 of the sixth embodiment performs the fault diagnosis in rotation for each memory die, in the same manner as the erasure of the memory cells as described for the arithmetic device 1 of the fifth embodiment. The arithmetic device 1 of the sixth embodiment then performs the logical operations using the memory dies in the banks other than the bank including the memory die which is being subjected to fault diagnosis.

Thus, the arithmetic device 1 of the sixth embodiment prevents the throughput of the logic circuit configured using the flash memory 20 from decreasing due to the fault diagnosis.

### Seventh Embodiment

Next, a seventh embodiment will be described.

As already described in the sixth embodiment, the flash memory 20 is deteriorated each time writing and erasing are performed. As the flash memory 20 is more deteriorated, the probability of errors occurring in reading and writing to the flash memory 20 becomes higher. For this reason, errors occur with a certain probability in logical operations using the flash memory 20.

Therefore, an arithmetic device 1 of a seventh embodiment comprises a mechanism to deal with errors in logical operations that are caused by the quality of the flash memory 20.

For example, when performing a certain NAND operation, the arithmetic device 1 of the seventh embodiment duplicates reading and writing for the memory cells for the NAND operation using multiple memory cells. This corresponds to performing a single NAND operation multiple times. These operations are desirably performed in parallel.

For example, the memory controller 10 duplicates reading and writing for a single NAND operation in parallel using three memory cells. The memory controller 10 then takes a majority vote of the read values of the three memory cells. Considering the probability of the flash memory 20 generating an error, it can be said that the read values which are incorrect are rarely in the majority.

Incidentally, as described in the fifth and sixth embodiments, the flash memory 20 includes multiple memory dies, and each of the multiple memory dies includes multiple blocks. In addition, each of the multiple blocks includes multiple pages. Reading and writing to the flash memory 20 are usually performed in units of pages.

Therefore, when the memory controller 10 duplicates reading and writing for a single NAND operation in parallel, the memory controller 10 performs them collectively using memory cells within the same page. Accordingly, the arithmetic device 1 of the seventh embodiment can prevent the decrease in throughput caused by duplicating reading and writing for a single NAND operation.

As described above, the arithmetic device 1 of the seventh embodiment can deal with errors in logical operations that are caused by the quality of the flash memory 20.

### Eighth Embodiment

Next, an eighth embodiment will be described.

In the above-described first embodiment, the example of logically constructing a NAND gate and a NOR gate with complete functionality as single units using the flash memory 20 has been described. In addition, it has been described that the arithmetic device 1 of the first embodiment can construct any logic circuit depending on the combination of NAND gates or NOR gates.

In the eighth embodiment, an example of a computer architecture that achieves processing equivalent to more complex circuits using only a flash memory and its read and write circuits will be described. This computer architecture is referred to as a Flash Memory Only Processor (FMOP).

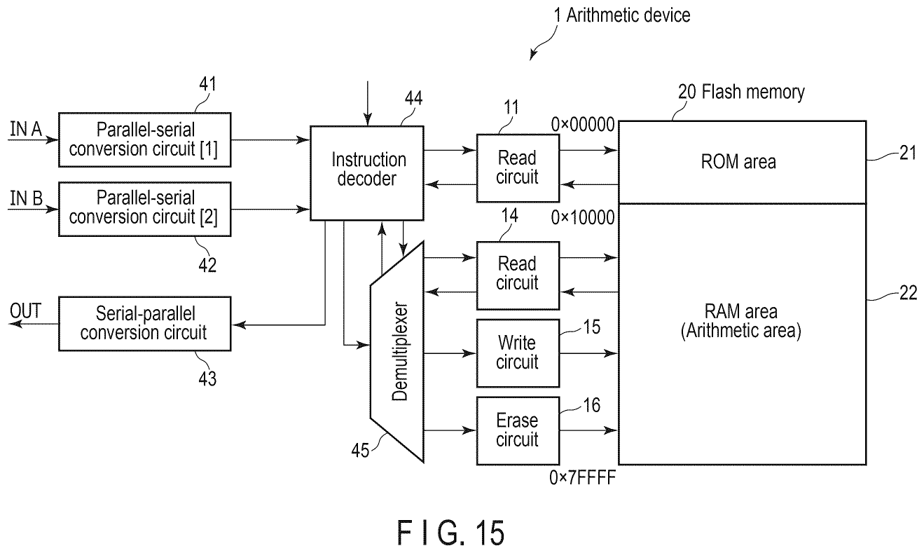

FIG. 15 is a view showing an example of an arithmetic device 1 of the eighth embodiment. The arithmetic device 1 of the eighth embodiment is configured to be able to correspond to an instruction structure to be described later, which is specified by FMOP. The arithmetic device 1 of the eighth embodiment performs logical operations on two inputs from input ports (IN) A and B, and outputs the results to an output port (OUT).

The arithmetic device 1 of the eighth embodiment, like the arithmetic device 1 of the first embodiment, includes a flash memory 20 in which a ROM area 21 and a RAM area (arithmetic area) 22 are defined. For example, “0x00000” written on a left side of a rectangle representing the flash memory 20 is an address of the flash memory 20. “0x” indicates hexadecimal notation. The capacity of the flash memory 20 chip is 4M bits, and the address is 19 bits, as an example.

Furthermore, the arithmetic device 1 of the eighth embodiment includes various circuits with the same functions as the ROM area read circuit 11, the arithmetic area read circuit 14, the arithmetic area write circuit 15, and the erase circuit 16, which have been described as the components of the memory controller 10 in the first embodiment. In FIG. 15, these circuits are shown as a read circuit 11, a read circuit 14, a write circuit 15, and an erase circuit 16.

The arithmetic device 1 of the eighth embodiment further includes a parallel-serial conversion circuit [1] 41, a parallel-serial conversion circuit [2] 42, a serial-parallel conversion circuit 43, an instruction decoder 44, and a demultiplexer 45.

Each of the input ports (IN) A and B and the output port (OUT) is assumed to have a width of 16 bits. The arithmetic device 1 can perform the logical operation of only one bit at a time. In other words, the logical operation of the arithmetic device 1 is completed for only one bit at a time. For this reason, the parallel-serial conversion circuit [1] 41 performs parallel-serial conversion of the input from the input port (IN) A. The parallel-serial conversion circuit [2] 42 performs parallel-serial conversion of the input from the input port (IN) B. In contrast, the serial-parallel conversion circuit 43 performs serial-parallel conversion of the calculation results obtained per one bit and outputs the results to the output port (OUT).

The instruction decoder 44 reads one step of the program stored in the ROM area 21 of the flash memory 20, via the read circuit 11. For example, when a control signal indicating the start of arithmetic operation is input, the instruction decoder 44 starts reading the program.

One step of the program is a set of instructions created in accordance with the instruction structure defined by FMOP. The instruction decoder 44 interprets this instruction set and controls the parallel-serial conversion circuit [1] 41, the parallel-serial conversion circuit [2] 42, the serial-parallel conversion circuit 43, the demultiplexer 45, the read circuit 11, the write circuit 15, and the erase circuit 16. The control of the read circuit 11, the write circuit 15, and the erase circuit 16 is selectively performed via the demultiplexer 45. In other words, the instruction decoder 44 controls the demultiplexer 45 to selectively control the read circuit 11, the write circuit 15, or the erase circuit 16.

The demultiplexer 45 relays the command sent from the instruction decoder 44 to one of the read circuit 14, the write circuit 15, and the erase circuit 16, based on the control signal supplied from the instruction decoder 44. The demultiplexer 45 also comprises a function of relaying the data sent from the read circuit 14 to the instruction decoder 44.

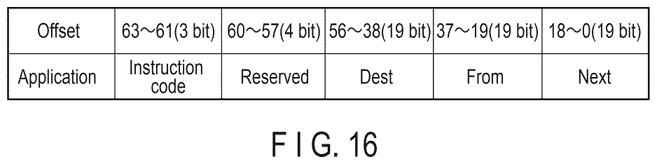

FIG. 16 is a view showing an example of the instruction structure specified by FMOP.

The instruction structure specified by FMOP constitutes an instruction set with one word (=8 bytes =64 bits). As shown in FIG. 16, the instruction set includes an “instruction code” field, a “reserved” field, a “dest” field, a “from” field, and a “next” field.

The “instruction code” field is a field for specifying the code corresponding to any one of total eight types of instructions defined by FMOP, such as the MOV instruction for performing the data transfer in the flash memory 20. Details of the instructions including MOV will be described later.

The “dest” field is, for example, a field for specifying a destination address of MOV.

The “from” field is, for example, a field for specifying a read address of MOV.

The “next” field is a field for specifying an address where an instruction set to be next fetched is stored, after executing the current instruction.

As described above, the instruction decoder 44 starts reading the program when, for example, a control signal indicating the start of operation is input. After reading the first instruction set from the flash memory 20, then the instruction decoder 44 controls the read circuit 11 based on the address specified in the “next” field of each instruction set to read the next instruction set from the flash memory 20. In other words, the arithmetic device 1 of the eighth embodiment does not require a program counter for sequentially reading the program stored in the ROM area 21 of the flash memory 20 in each step. By not including a program counter, the arithmetic device 1 of the eighth embodiment has advantages that (1) a register dedicated to program counting is unnecessary and that (2) an adder for address increment is unnecessary.

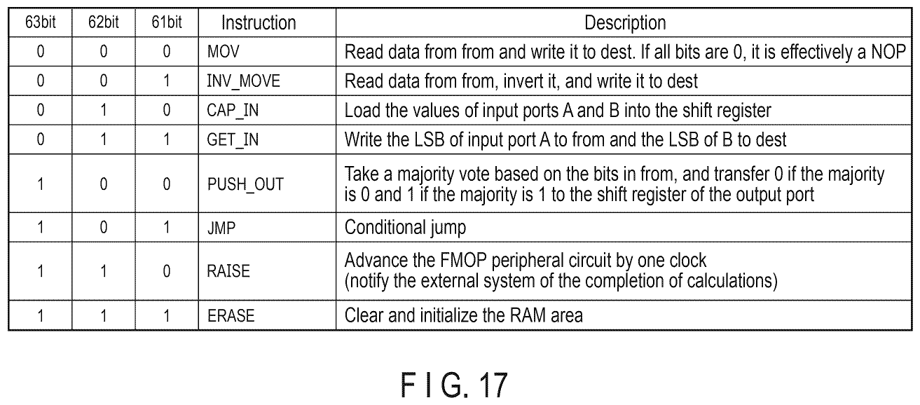

FIG. 17 is a table showing an example of an instruction code defined by FMOP.

The “instruction code” field is the first three bits of a one-word instruction set (see FIG. 16). By these 3 bits, one of “MOV”, “INV_MOVE”, “CAP_IN”, “GET_IN”, “PUSH_OUT”, “JMP”, “RAISE”, and “ERASE” is specified.

MOV indicates reading the data from the address specified in the “from” field and writing the data to the address specified in the “dest” field. Incidentally, no action is taken if both the “from” field and the “dest” field are all 0. In MOV, the instruction decoder 44 controls the read circuit 14 and the write circuit 15 via the demultiplexer 45.

INV_MOVE indicates reading the data from the address specified in the “from” field, inverting the data, and writing the data to the address specified in the “dest” field. In INV_MOVE, the instruction decoder 44 also controls the read circuit 14 and the write circuit 15 via the demultiplexer 45.

CAP_IN indicates loading the values of input ports (IN) A and B into the shift register. In CAP_IN, the instruction decoder 44 controls the parallel-serial conversion circuit [1] 41 and the parallel-serial conversion circuit [2] 42.

GET_IN indicates writing the value of the least significant bit (LSB) of input port (IN) A to the address specified in the “from” field, and writing the value of the least significant bit (LSB) of the input port (IN) B to the address specified in the “dest” field. In GET_IN, the instruction decoder 44 controls the write circuit 15 via the demultiplexer 45.

PUSH_OUT indicates taking a majority on the bits held at the address specified in the “from” field, transferring 0 to the shift register of the output port (OUT) if the majority is 0, and transferring 1 to the shift register of the output port (OUT) if the majority is 1. In PUSH_OUT, the instruction decoder 44 controls the read circuit 14 via the demultiplexer 45 and also controls the serial-parallel conversion circuit 43.

Regarding the majority, the read and write operations of the flash memory 20 fail with a certain probability. Therefore, in the eighth embodiment, the arithmetic device 1 performs the read and write operations on the flash memory 20 by converting, for example, Ox01 to 0xff. In other words, the arithmetic device 1 of the eighth embodiment performs eight read and write operations in parallel. By taking the majority decision of these eight operations, the arithmetic device 1 of the eighth embodiment enables error correction for the read and write operations to be performed.

JMP indicates a conditional jump. RAISE indicates advancing the peripheral circuit of the FMOP by one clock. This is to notify the outside of the calculation completion timing.

ERASE indicates erasing the RAM area 22 of the flash memory 20 and initializing. In ERASE, the instruction decoder 44 controls the erase circuit 16 via the demultiplexer 45.

By describing a program composed of the instruction set including the above-described instruction codes, the arithmetic device 1 of the eighth embodiment can execute any logical operation using only the flash memory 20 and its read and write circuits.

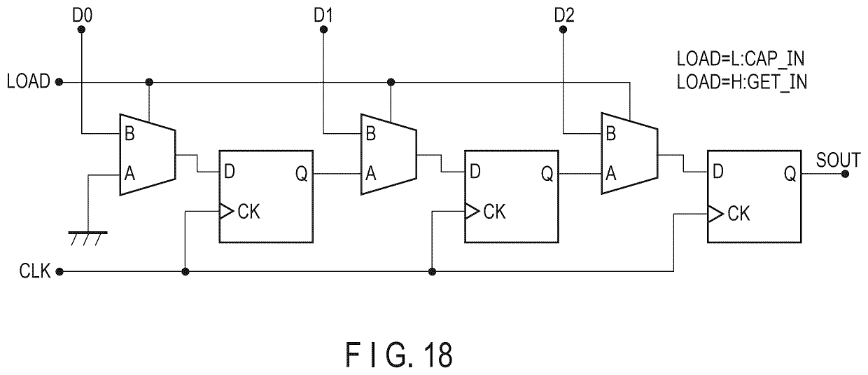

FIG. 18 is a diagram showing a configuration example of the parallel-serial conversion circuit [1] 41 and the parallel-serial conversion circuit [2] 42. In this example, the input from the input port (IN) originally having a width of 16 bits is simplified to the input having a width of 3 bits.

The parallel-serial conversion circuit [1] 41 and the parallel-serial conversion circuit [2] 42 are circuits that operate in response to the instruction codes “CAP_IN” and “GET_IN” described with reference to FIG. 17. First, regarding the instruction code “CAP_IN”, the parallel-serial conversion circuit [1] 41 and the parallel-serial conversion circuit [2] 42 are configured to take the values of the input ports (IN) A and B in the shift register when the LOAD signal line becomes L (Low). In addition, secondly, regarding the command code “GET_IN”, the parallel-serial conversion circuit [1] 41 and the parallel-serial conversion circuit [2] 42 are configured to write the value of the least significant bit of the input port (IN) A to the address specified in the “from” field and to write the value of the least significant bit of the input port (IN) B to the address specified in the “dest” field when the LOAD signal line is set to H (High).

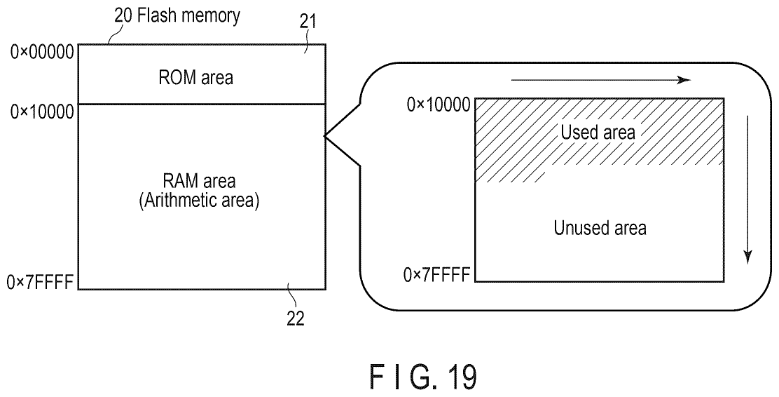

FIG. 19 is a diagram showing an example of a memory map of the arithmetic device of the eighth embodiment. The arithmetic device 1 of the eighth embodiment does not include a register including a program counter. Therefore, only the flash memory 20 included in the arithmetic device 1 of the eighth embodiment is mapped on the memory map of the arithmetic device 1 of the eighth embodiment.

In the flash memory 20 included in the arithmetic device 1 of the eighth embodiment, the ROM area 21 and the RAM area (arithmetic area) 22 are defined as described above.

In the ROM area 21, a program consisting of the instruction set including the instruction codes described with reference to FIG. 17 is stored. Since it is assumed that the instruction structure specified by FMOP constitutes the instruction set in one word, up to 8,192 steps of the program can be stored in the ROM area 21 in the example shown in FIG. 19.

The RAM area 22 is a location where reading and writing for NAND operations and NOR operations are executed, and also a location where intermediate results of arbitrary logical operations executed by combining NAND operations and NOR operations are stored.

In the arithmetic device 1 of the eighth embodiment, when the area of flash memory 20 allocated as RAM area 22 is exhausted, erasure is required for initialization. The instruction code “ERASE” described with reference to FIG. 17 is used for initializing the RAM area 22.

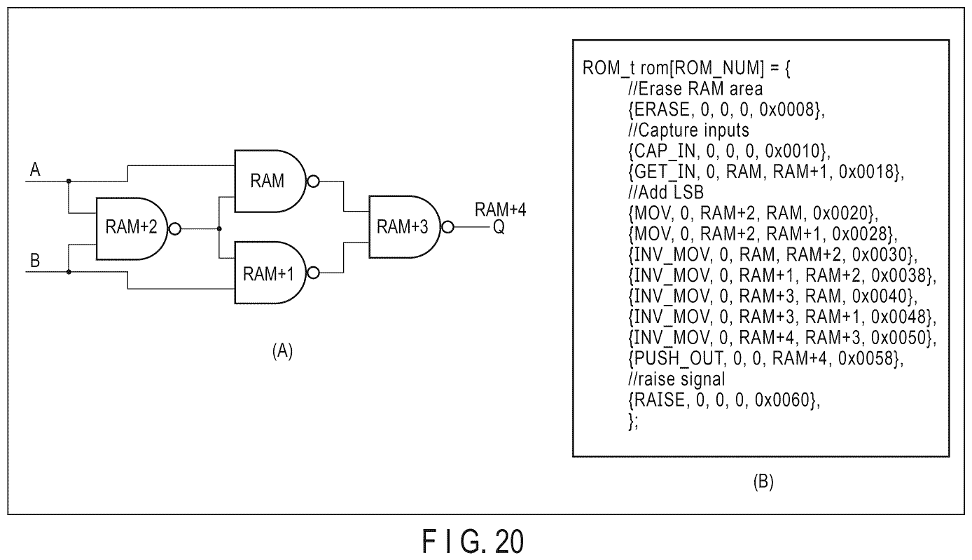

FIG. 20 is a diagram showing an example of execution of a 1-bit addition using FMOP, i.e., the computer architecture to which the arithmetic device 1 of the eighth embodiment is applied.

FIG. 20(A) is a diagram showing a configuration example of a one-bit addition circuit using a combination of NAND gates. In contrast, FIG. 20(B) is a diagram showing an example of the program code in which steps of a 1-bit addition executed by the 1-bit addition circuit in FIG. 20(A) are described using the instruction codes (instruction set) defined by FMOP. Codes of a program operating under the control of an FMOP emulator composed of C++, which is one of general-purpose programming languages, are shown as an example.

Thus, the arithmetic device 1 of the eighth embodiment can execute any logical operation composed of a combination of NAND gates and a combination of NOR gates by sequentially reading the programs described in accordance with FMOP from the ROM area 21 and executing NAND operations and NOR operations using the RAM area 22.

Furthermore, the arithmetic device 1 of the eighth embodiment is configured to correspond to the instruction structure specified by FMOP in which the address where the instruction to be next fetched is stored is indicated by the “next” field of each instruction set, thereby realizing the processing equivalent to that of a more complex circuit using only the flash memory 20 and its read and write circuits.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

The embodiments include the following features.

### Note 1

An arithmetic device comprising:
a nonvolatile memory including multiple memory cells each of which being capable of becoming any one of a first to M states (M is L-th power of 2; L is a natural number greater than or equal to 2); and
a memory controller configured to control the nonvolatile memory, wherein
the memory controller is configured to
   define the first state as a state in which a first value is stored, define state other than the first state as states in which a second value is stored, and initialize the memory cell in the first state,
   maintain a current state of the memory cell in response to a request to write an L-digit value composed of a combination of the only first values to the memory cell,
   shift, in response to a request to write an L-digit value composed of a combination of the first value and the second value or an L-digit value composed of a combination of the only second values to the memory cell, the memory cell to any one of the second state to the M state in accordance with the L-digit value, and
in response to a request to read a value stored in the memory cell, acquires the first value or the second value obtained by inverting the first value between the first value and the second value as the value stored in the memory cell when the memory cell is in the first state, and acquires the second value or the first value obtained by inverting the second value between the first value and the second value as the value stored in the memory cell when the memory cell is in the state other than the first state, and
the arithmetic device is capable of performing logical operations including N input AND operation, N input NAND operation, N input OR operation, or N input NOR operation by writing the first value or the second value to the memory cell N times and reading the value stored in the memory cell, the N being a natural number greater than or equal to 2.

What is claimed is

1. An arithmetic device comprising:
a nonvolatile memory including multiple memory cells each of which being capable of becoming any one of a first state and a second state; and
a memory controller configured to control the nonvolatile memory, wherein
the memory controller is configured to
define the first state as a state in which a first value is stored, define the second state as a state in which a second value is stored, and initialize the memory cell in the first state,
maintain a current state of the memory cell in response to a request to write the first value to the memory cell,
shift the memory cell to the second state in response to a request to write the second value to the memory cell, and
acquire the first value or the second value stored in the memory cell, or the second value or the first value obtained by inverting the first value or the second value stored in the memory cell, between the first value and the second value, as a value stored in the memory cell, in response to a request to read the value stored in the memory cell, and
the arithmetic device is capable of performing logical operations including N input AND operation, N input NAND operation, N input OR operation, or N input NOR operation by writing the first value or the second value to the memory cell N times and reading the value stored in the memory cell, the N being a natural number greater than or equal to 2.

2. The arithmetic device of claim 1, wherein
a computer is capable of being constructed by securing four areas (1) a first area where a program for performing the logical operations is stored, (2) a second area used for the logical operations, (3) a third area used as a work area of the program, and (4) a fourth area where information used for the program is stored, in an area of the nonvolatile memory.

3. The arithmetic device of claim 1, wherein
a program operating in the memory controller inverts the first value or the second value read from the memory cell, between the first value and the second value.

4. The arithmetic device of claim 1, wherein
a NOT gate inverting the first value or the second value output from the nonvolatile memory between the first value and the second value is provided between the memory controller and the nonvolatile memory.

5. The arithmetic device of claim 1, wherein
the nonvolatile memory inverts correspondence between the first and second states and the first and second values.

6. The arithmetic device of claim 1, wherein
each of the multiple memory cells is capable of further becoming a state other than the first state or the second state, and
the memory controller is configured to define a state other than the first state as a state in which the second value is stored.

7. The arithmetic device of claim 1, wherein
the memory controller is capable of switching a first mode to control the nonvolatile memory to perform the logical operations and a second mode to control the nonvolatile memory to function as a storage storing data.

8. The arithmetic device of claim 1, wherein
the nonvolatile memory includes multiple memory dies each being operable independently, and
the memory controller is configured to perform the plural N input AND operation, N input NAND operation, N input OR operation, or N input NOR operation included in the logical operations in parallel using the plural memory dies.

9. The arithmetic device of claim 1, wherein
the nonvolatile memory includes multiple memory dies each being operable independently, and
the memory controller is configured to circularly perform initialization of the memory cell to the first state one by one from the multiple memory dies.

10. The arithmetic device of claim 1, wherein
the nonvolatile memory includes multiple memory dies each being operable independently, and
the memory controller is configured to circularly perform fault diagnosis of the nonvolatile memory one by one from the multiple memory dies.

11. The arithmetic device of claim 1, wherein
the memory controller is configured to take a majority vote by performing the N input AND operation, N input NAND operation, N input OR operation, or N input NOR operation included in the logical operations multiple times for each operation.

12. A memory controller which controls a nonvolatile memory including multiple memory cells each being capable of becoming any one of a first state and a second state, wherein
the memory controller is configured to
define the first state as a state in which a first value is stored, define the second state as a state in which a second value is stored, and initialize the memory cell in the first state,
maintain a current state of the memory cell in response to a request to write the first value to the memory cell,
shift the memory cell to the second state in response to a request to write the second value to the memory cell, and
acquire the first value or the second value stored in the memory cell, or the second value or the first value obtained by inverting the first value or the second value stored in the memory cell, between the first value and the second value, as a value stored in the memory cell, in response to a request to read a value stored in the memory cell,
thereby being capable of performing logical operations including N input AND operation, N input NAND operation, N input OR operation, or N input NOR operation by making a request to write the first value or the second value to the memory cell N times (where N is a natural number greater than or equal to 2) and then reading the value stored in the memory cell.

13. An arithmetic method of an arithmetic device comprising a nonvolatile memory including multiple memory cells each of which being capable of becoming any one of a first state and a second state, and a memory controller which controls the nonvolatile memory, the method comprising:
by the memory controller,
defining the first state as a state in which a first value is stored, defining the second state as a state in which a second value is stored, and initializing the memory cell in the first state,
when receiving a request to write the first value to the memory cell, maintaining a current state of the memory cell and ends a process corresponding to the request,
when receiving a request to write the second value to the memory cell, shifting the memory cell to the second state and ends a process corresponding to the request, and
acquiring the first value or the second value stored in the memory cell, or the second value or the first value obtained by inverting the first value or the second value stored in the memory cell, between the first value and the second value, as a value stored in the memory cell, in response to a request to read a value stored in the memory cell,
thereby being capable of performing logical operations including N input AND operation, N input NAND operation, N input OR operation, or N input NOR operation by making a request to write the first value or the second value to the memory cell N times (where N is a natural number greater than or equal to 2) and then reading the value stored in the memory cell.

14. An arithmetic device comprising:
a nonvolatile memory including a plurality of memory cells having a property of holding 1 in an initial state and, once a value of 0 is written, continuing to hold 0 even if 1 is subsequently written;
a first read circuit configured to read a program stored in a first area of the nonvolatile memory;
a second read circuit configured to read values held in the memory cells in the second area of the nonvolatile memory;
a write circuit configured to write 0 or 1 to the memory cells in the second area of the nonvolatile memory;
an erase circuit configured to initialize the memory cells where writing is executed by the write circuit in the second area of the nonvolatile memory; and
an instruction decoder configured to control the first read circuit, the second read circuit, the write circuit, and the erase circuit based on an instruction set included in the program read by the first read circuit, wherein
the program is described with the instruction set to execute N-input AND operation, N-input NAND operation, N-input OR operation, or N-input NOR operation by writing to the same memory cell at N times, and to execute a predetermined operation by a combination of the N-input AND operation, the N-input NAND operation, the N-input OR operation, or the N-input NOR operation, and
the instruction set includes an address indicating a position of the instruction set in the program to be next processed.
